(19) United States
(12) Patent Application Publication
(10) Pub. No.: US 2024/0203693 A1
(43) Pub. Date: Jun. 20, 2024

(54) PLASMA PROCESSING EQUIPMENT

(71) Applicant: SAMSUNG ELECTRONICS CO., LTD., Suwon-si (KR)

(72) Inventors: Hee Won MIN, Suwon-si (KR); Song Yun KANG, Suwon-si (KR); Ju Ho KIM, Suwon-si (KR); Seok Hwan BAE, Suwon-si (KR); Dong Yun YEO, Suwon-si (KR); Kui Hyun YOON, Suwon-si (KR); Seung Bin LIM, Suwon-si (KR); Ji Yun JU, Suwon-si (KR); Seo Yeon CHOI, Suwon-si (KR)

(73) Assignee: SAMSUNG ELECTRONICS CO., LTD., Suwon-si (KR)

(21) Appl. No.: 18/532,468

(22) Filed: Dec. 7, 2023

(30) Foreign Application Priority Data
Dec. 14, 2022 (KR) 10-2022-0174957

(51) Int. Cl. H01J 37/32

(52) U.S. Cl. CPC H01J 37/3244; H01J 37/32642; H01J 37/32715; H01J 2237/006; H01J 2237/334

(57) ABSTRACT

A plasma processing equipment includes: an electrostatic chuck on which a substrate is provided; a gas filling unit provided between the substrate and the electrostatic chuck; a gas supply unit extending through the electrostatic chuck and connected to the gas filling unit, the gas supply unit comprising a plurality of first nonconductive balls; and a focus ring provided along an edge of the electrostatic chuck.

### CROSS-REFERENCE TO RELATED APPLICATION

This application claims priority from Korean Patent Application No. 10-2022-0174957, filed on Dec. 14, 2022, in the Korean Intellectual Property Office and all the benefits accruing therefrom under 35 U.S.C. § 119, the content of which is incorporated by reference herein in its entirety.

### BACKGROUND

### 1. Field

The disclosure relates to a plasma processing equipment.

### 2. Description of Related Art

Due to an internal miniaturization and a high integration of a next-generation apparatus, processes using a plasma processing equipment have been increasingly difficult. For example, as patterns of semiconductor wafer substrates are further miniaturized, there is a need to increase power of a power supply provided to the equipment for plasma generation in an etching process using the plasma. At this time, as a voltage applied to the equipment increases, an arcing phenomenon may occur in a hole portion in which gas or plasma mainly exists among the components of the equipment. Accordingly, technologies for preventing the arcing phenomenon are being researched.

### SUMMARY

Example embodiments provide a plasma processing equipment having an improved withstand voltage performance.

According to an aspect of an example embodiment, a plasma processing equipment includes: an electrostatic chuck on which a substrate is provided; a gas filling unit provided between the substrate and the electrostatic chuck; a gas supply unit extending through the electrostatic chuck and connected to the gas filling unit, the gas supply unit comprising a plurality of first nonconductive balls; and a focus ring provided along an edge of the electrostatic chuck.

According to an aspect of an example embodiment, a plasma processing equipment includes: an electrostatic chuck on which a substrate is provided; a gas filling unit provided above the electrostatic chuck and configured to provide a gas pressure to a lower side of the substrate; a gas supply unit connected to the gas filling unit and configured to supply a gas to the gas filling unit, the gas supply unit comprising a plurality of first nonconductive balls; and a gas exhaust unit connected to the gas filling unit and configured to discharge the gas supplied from the gas supply unit to the gas filling unit.

According to an aspect of an example embodiment, a plasma processing equipment includes: a chamber; a coil configured to induce an electric field for generating a plasma inside the chamber; an electrostatic chuck inside the chamber and on which a substrate is provided; a gas filling unit configured to provide a gas pressure to a lower side of the substrate; a gas supply unit connected to the gas filling unit and configured to supply a gas to the gas filling unit, the gas supply unit comprising a plurality of first nonconductive balls; a gas exhaust unit connected to the gas filling unit, and configured to discharge the gas to the gas filling unit; a focus ring provided in an annular shape along an edge of the electrostatic chuck; a first lift pin hole comprising a first lift pin and a plurality of second nonconductive balls, wherein the first lift pin penetrates the focus ring and the edge of the electrostatic chuck and is configured to adjust a height of the focus ring; and a second lift pin hole comprising a second lift pin and a plurality of third nonconductive balls, wherein the second lift pin is provided below the substrate, and configured to penetrate the electrostatic chuck to adjust the height of the substrate.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and/or other aspects will become apparent and more readily appreciated from the following description of the embodiments, taken in conjunction with the accompanying drawings in which:

FIGS. 1 to 5 are example diagrams for explaining an electrostatic chuck, a gas filling unit, and a gas supply unit included in the plasma processing equipment according to some embodiments;

FIG. 6 is an example diagram for explaining a gas exhaust unit included in the plasma processing equipment according to some embodiments;

FIGS. 7 to 9 are example diagrams for explaining the lift pin and the lift pin hole included in the plasma processing equipment according to some embodiments;

FIG. 10 is an exemplary diagram for describing a plasma processing equipment according to some embodiments;

FIG. 11 is an example diagram for explaining the effects of the plasma processing equipment according to some embodiments;

FIG. 12 is an example top view of a part of the plasma processing equipment of FIG. 11 viewed from above;

FIGS. 13 and 14 are example diagrams for explaining the effects of the plasma processing equipment according to some embodiments; and

FIG. 15 is an example graph for explaining the effect of the plasma processing equipment according to some embodiments.

### DETAILED DESCRIPTION

Hereinafter, a plasma processing equipment according to some embodiments will be described with reference to the accompanying drawings.

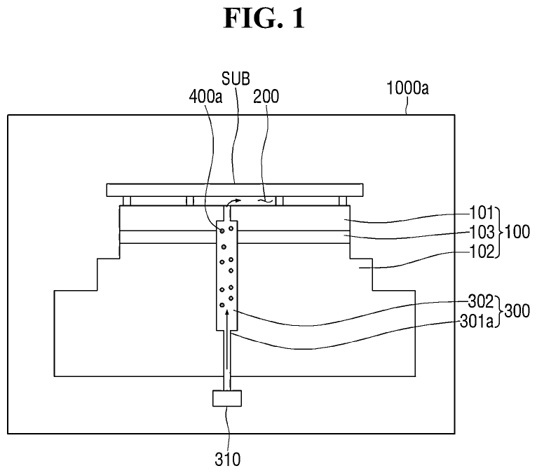

FIGS. 1 to 5 are example diagrams for explaining an electrostatic chuck, a gas filling unit, and a gas supply unit included in the plasma processing equipment according to some embodiments.

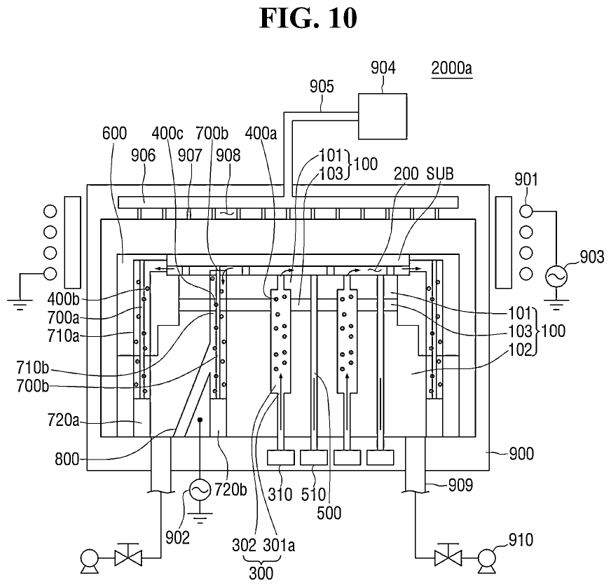

Referring to FIG. 1, first, a plasma processing equipment 1000a according to some embodiments may include an electrostatic chuck 100, a gas filling unit 200, and a gas supply unit 300. The plasma processing equipment 1000a may be a plasma etching device such as an inductively coupled plasma etching device or a conductively coupled plasma etching device. However, the embodiment is not limited to the plasma etching device, and the plasma processing equipment 1000a may be another device that processes the semiconductor wafer substrate SUB using a plasma. A detailed structure of the plasma processing equipment 1000a will be described below with reference to FIG. 10.

The substrate SUB may be placed or provided on the electrostatic chuck 100. The electrostatic chuck 100 may horizontally fix the substrate SUB such as a wafer, or may hold a glass substrate SUB of an LCD to be held horizontally. The electrostatic chuck 100 may include a puck 101, a base plate 102, and a bonding layer 103. The puck 101 may include a conductive member such as aluminum, and may include internal electrodes. The internal electrodes of the puck 101 may be connected to an external DC power supply and applied with a DC voltage, thereby electrostatically adsorbing the substrate SUB onto the electrostatic chuck 100 by an electrostatic force.

The base plate 102 may include a conductive member such as aluminum, and a coolant for cooling the temperature of the electrostatic chuck 100 may flow inside. In some embodiments, a high-frequency power may be applied to the base plate 102 to from an electric field. That is, the base plate 102 may include electrodes for providing the power supply to the electrostatic chuck 100. In some embodiments, although the power supply provided to the electrostatic chuck 100 through the base plate 102 may be a radio frequency (RF) power supply, the embodiments are not limited thereto. For example, the power supply provided to the electrostatic chuck 100 through the base plate 102 may be a microwave power supply. The bonding layer 103 may bond the puck 101 and the base plate 102, by including silicon.

The gas filling unit 200 may be placed or provided between the substrate SUB and the electrostatic chuck 100. For example, as shown in FIG. 1, the gas filling unit 200 may correspond to an empty space between the substrate SUB and the electrostatic chuck 100. However, the embodiment is not limited thereto, and the gas filling unit 200 may be a space that exists inside the electrostatic chuck 100 and abuts against a lower side of the substrate SUB. The gas filling unit 200 may be placed or provided above the electrostatic chuck 100. The gas filling unit 200 may be supplied with gas from the gas supply unit 300 to fill the gas inside, and may provide a gas pressure to the lower side of the substrate SUB. In some embodiments, the temperature of the substrate SUB may vary depending on the amount of gas pressure provided to the lower side of the substrate SUB through the gas filling unit 200. Therefore, in some embodiments, the amount of gas provided to the gas filling unit 200 through the gas supply unit 300 may be controlled to adjust the temperature of the substrate SUB.

The gas supply unit 300 may supply the gas injected from a gas pressure controller 310 to the gas filling unit 200. In some embodiments, the gas flowing in from the gas pressure controller 310 to the gas supply unit 300 may be, but is not limited to, an inert gas including helium (He) or argon (Ar).

The gas supply unit 300 may include a gas inlet 301a into which a gas flows and a gas supply pipe 302. The gas inlet 301a may be a passage through which the gas is delivered from the gas pressure controller 310 to the gas supply pipe 302. According to the embodiment, the inflow of gas from the gas pressure controller 310 to the gas supply pipe 302 may be adjusted by opening and closing the entrance of the gas inlet 301a. For example, the gas may be adjusted not to be delivered from the gas pressure controller 310 to the gas supply pipe 302, by closing the entrance of the gas inlet 301a.

In some embodiments, the gas supply pipe 302 may include a plurality of nonconductive balls 400a therein. When the gas flows into the gas supply pipe 302, the plurality of nonconductive balls 400a may repeat a random motion inside the gas supply pipe 302 depending on the pressure of the flowing gas. The plurality of nonconductive balls 400a may include, but are not limited to, nonconductor materials such as ceramics. In addition, the plurality of nonconductive balls 400a may repeat the random motion by including an elastic material, even if the nonconductive balls 400a collide with each other in the gas supply pipe 302 or collide with the inner walls of the gas supply pipe 302. In some embodiments, the radius of the plurality of nonconductive balls 400a may be, but is not limited to, in the range from 0.5 mm to 1.0 mm.

As the voltage of the power supplied to the electrostatic chuck 100 through the base plate 102 increases, an arcing phenomenon in which the interior of the gas supply unit 300 is burned by high ion energy may occur. In some embodiments, by placing a plurality of nonconductive balls 400a that move randomly depending on the pressure of the gas inside the gas supply pipe 302, the arcing phenomenon may be prevented by suppressing the discharge due to the acceleration energy of electron when the gas passes through the inside of the gas supply pipe 302. That is, the nonconductive balls 400a randomly moving inside the gas supply pipe 302 may prevent the arcing phenomenon from occurring on the inner wall of the gas supply unit 300 including the gas supply pipe 302, by disturbing the gas molecules so that they do not obtain an acceleration energy to pass through the gas supply pipe 302 quickly.

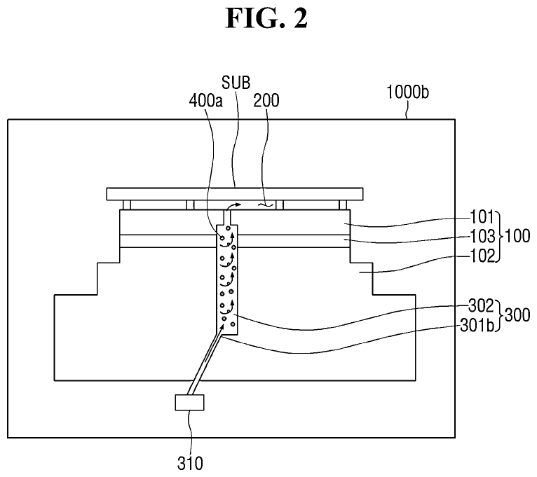

Next, referring to FIG. 2, the gas inlet 301b included in the plasma processing equipment 1000b according to some embodiments may be formed or provided on the side part of the gas supply pipe 302 unlike the gas inlet 301a shown in FIG. 1. When the gas inlet 301b is formed or provided at the side part of the gas supply pipe 302, compared to the case where the gas inlet 301a (shown in FIG. 1) is formed or provided at the center of the gas supply pipe 302, more disturbances may occur in the motion of the nonconductive balls 400a depending on the pressure of the gas flowing into the gas supply pipe 302 through the gas inlet 301b. Accordingly, since more turbulences also occur in the motion of the gas molecules passing through the inside of the gas supply pipe 302, a speed of the gas molecules passing through the inside of the gas supply pipe 302 may become further slower. Therefore, it is possible to prevent an arcing phenomenon from occurring on the inner wall of the gas supply unit 300 including the gas supply pipe 302.

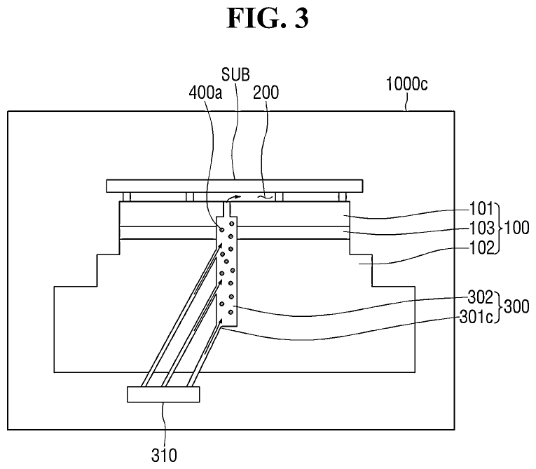

Referring to FIG. 3, next, two or more gas inlets 301c included in the plasma processing equipment 1000c according to some embodiments may be formed or provided on the side part of the gas supply pipe 302. Hereinafter, in FIGS. 3 to 5, a case where three gas inlets 301c are formed or provided on the side part of the gas supply pipe 302 will be described as an example, as shown in FIG. 3. At this time, although the gas inlet 301c may be supplied with gas from one gas pressure controller 310, the embodiments are not limited thereto. For example, the gas inlets 301c may be supplied with gas from the gas pressure controllers different from each other. According to the embodiment, the gas inlets 301c may control whether to make the gas supplied from the gas pressure controller 310 flow into the gas supply pipe 302. For example, a plug may be formed or provided inside each gas inlet 301c to control whether the gas flows in.

In some embodiments, a total volume of nonconductive balls 400a included inside the gas supply pipe 302 may be 20% or less of the volume of the gas supply pipe 302 per number of gas inlets 301c connected to the gas supply pipe 302. For example, when the gas supply pipe 302 is connected to one of the gas inlets 301c, the total volume of the nonconductive balls 400a included inside the gas supply pipe 302 may be 20% or less of the volume of the gas supply pipe 302. In addition, when the gas supply pipe 302 is connected to two of the gas inlets 301c, the total volume of the nonconductive balls 400a included in the gas supply pipe 302 may be 40% or less of the volume of the gas supply pipe 302. Also, when the gas supply pipe 302 is connected to all the three gas inlets 301c, the total volume of the nonconductive balls 400a included inside the gas supply pipe 302 may be 60% or less of the volume of the gas supply pipe 302. In this way, a threshold value of the total volume of the nonconductive balls 400a included inside the gas supply pipe 302 may increase by 20% of the total volume of the gas supply pipe 302, each time the number of gas inlets 301c which is connected to the gas supply pipe 302 (i.e., which makes the gas flow into the gas supply pipe 302) increases by one. The number and size of the plurality of nonconductive balls 400a may be determined, on the basis of the threshold value of the total volume of the nonconductive balls 400a included inside the gas supply pipe 302.

If the total volume of the nonconductive balls 400a included inside the gas supply pipe 302 is greater than 20% of the volume of the gas supply pipe 302 when the gas supply pipe 302 is connected to one of the gas inlets 301c, since the speed of the gas molecules passing through the gas supply pipe 302 may become too slow, a sufficient amount of gas may not reach the gas filling unit 200 or the time taken for process may excessively increase.

Also, in some embodiments, whether to make the gas flow from each gas inlet 301c into the gas supply pipe 302, i.e., the number of gas inlets 301c connected to the gas supply pipe 302 may be determined depending on the voltage magnitude of the power supply provided to the electrostatic chuck 100.

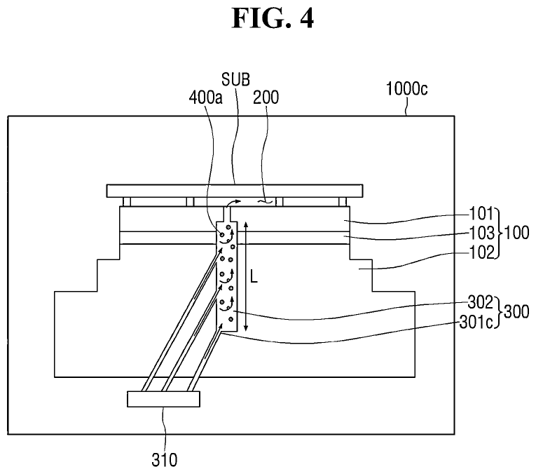

For example, referring to FIG. 4, when the voltage of the power supply provided to the electrostatic chuck 100 is relatively high, it may be highly necessary to improve the withstand voltage performance inside the gas supply unit 300 to prevent the arcing phenomenon. In this case, all the gas inlets 301c may be opened to control the gas to flow in from all the gas inlets 301c. At this time, all the nonconductive balls 400a inside the gas supply pipe 302 may move randomly depending on the pressure of the gas. For example, assuming the total length of the gas supply pipe 302 is L, all the nonconductive balls 400a existing in the inner zone of the gas supply pipe 302 corresponding to the length L may move randomly depending on the pressure of the gas. As a result, since the speed of gas molecules passing through the gas supply pipe 302 becomes slow, the withstand voltage performance inside the gas supply unit 300 may be improved.

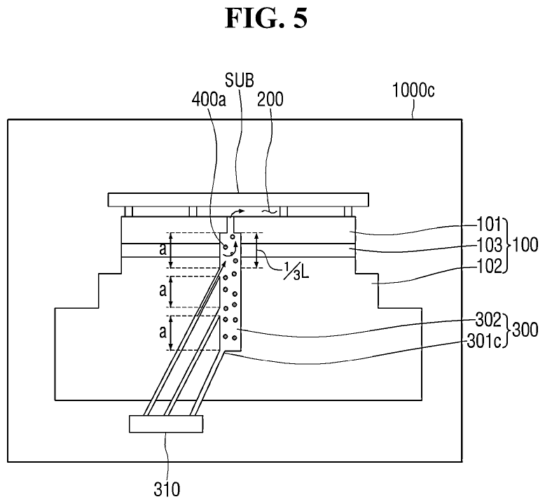

Next, referring to FIG. 5, when the voltage of the power supply provided to the electrostatic chuck 100 is relatively small, the necessity of improving conductance of the gas molecules passing through the gas supply pipe 302 to increase the speed of the process may be greater than the necessity of improving the withstand voltage performance inside the gas supply unit 300 to prevent the arcing phenomenon. In this case, only the uppermost gas inlet of the gas inlets 301c is opened, and the remaining gas inlets are closed so that the gas may be controlled to flow in only through the uppermost gas inlet. In some embodiments, the gas inlets 301c may be spaced apart by the same interval (e.g., a). At this time, the nonconductive balls 400a existing in the zone corresponding to the uppermost gas inlet in the inner zone of the gas supply pipe 302 may repeat the random motion. For example, assuming the total length of the gas supply pipe is L, the nonconductive balls 400a existing in the inner zone of the gas supply pipe 302 corresponding to a length (⅓)L corresponding to the uppermost gas inlet may move randomly depending on the pressure of the gas. In addition, the nonconductive balls 400a existing in the zone corresponding to the remaining gas inlets other than the uppermost end in the inner zone of the gas supply pipe 302 do not move because the gas does not flow in, or may move relatively little compared to the nonconductive balls 400a existing in the zone corresponding to the uppermost gas inlet.

That is, when the gas flows only through the uppermost gas inlet, the path (⅓)L along which the gas molecules move is shortened compared to the path L along which the gas molecules move when the gas flows in through all the gas inlets. As a result, the conductance of gas molecules passing through the gas supply pipe 302 is improved, and the time taken for the entire process may be shortened.

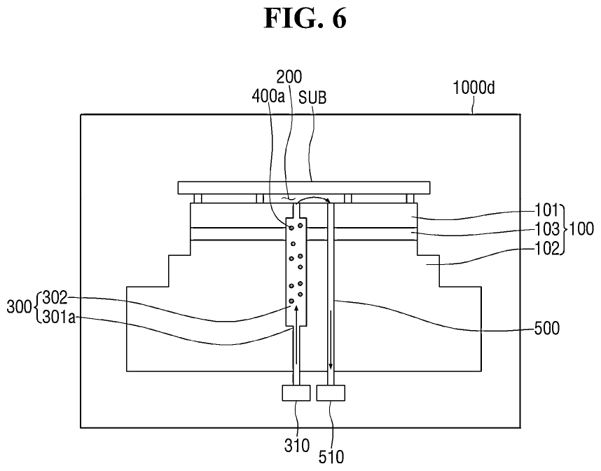

FIG. 6 is an example diagram for explaining a gas exhaust unit included in the plasma processing equipment according to some embodiments.

Referring to FIG. 6, a plasma processing equipment 1000d according to some embodiments may include a gas exhaust unit 500 that penetrates the electrostatic chuck 100 and is connected to the gas filling unit 200. The gas exhaust unit 500 may be connected to the exhaust pump 510 to discharge the gas filled in the gas filling unit 200. In this way, since the plasma processing equipment 1000d according to some embodiments may include the gas supply unit 300 and the gas exhaust unit 500, it may have a structure in which the gas provided to the gas filling unit 200 circulates. Accordingly, it is possible to quickly change the amount of gas filled in the gas filling unit 200 and quickly change the pressure of the gas provided to the lower side of the substrate SUB in the process operation.

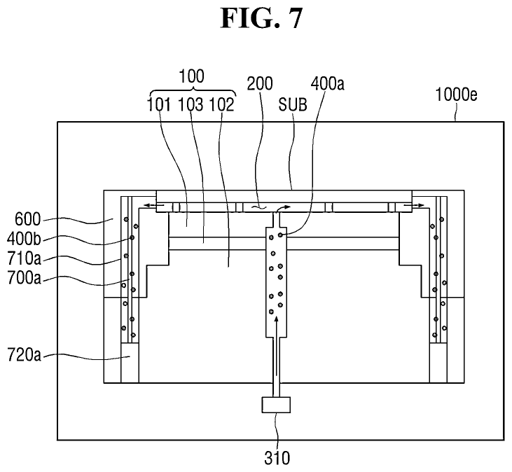

FIGS. 7 to 9 are example diagrams for explaining the lift pin and the lift pin hole included in the plasma processing equipment according to some embodiments.

Referring first to FIG. 7, a plasma processing equipment 1000e according to some embodiments may include a focus ring 600, a lift pin 700a, and a lift pin hole 710a placed or provided (annularly) along the edge of the electrostatic chuck 100.

The focus ring 600 may be made of a dielectric material, an insulating material, or the like to uniformly deliver an electric field onto the substrate SUB, and may include both a dielectric material and an insulating material, as another embodiment. For example, the focus ring 600 may include at least one of aluminum oxide (Al₂O₃), aluminum nitride (AlN), silicon (Si), silicon oxide (SiO₂), quartz, silicon carbide (SiC), and yttrium oxide (Y₂O₃).

The lift pin 700a may be formed or provided to penetrate the focus ring 600 and the edge of the electrostatic chuck 100. The lift pin 700a may be placed or provided inside the lift pin hole 710a, and may move up and down through the lift pin holder 720a to adjust the height of the focus ring 600. For example, when plasma is irradiated to the top of the focus ring 600 in the course of performing the process and the top of the focus ring 600 is etched, the lift pin 700a may increase the height of the focus ring 600 correspondingly. In this way, the lift pin 700a may adjust the height of the focus ring 600 to adjust a height relationship between the focus ring 600 and the substrate SUB.

The lift pin hole 710a may be formed or provided to penetrate the focus ring 600 and the edge of the electrostatic chuck 100, and may include a plurality of nonconductive balls 400b therein. The plurality of nonconductive balls 400b may include, but are not limited to, nonconductor materials such as ceramics. Gas may flow from the gas filling unit 200 into the lift pin hole 710a. That is, the gas supplied from the gas supply unit 300 to the gas filling unit 200 may flow into the lift pin hole 710a. When gas flows into the lift pin hole 710a, the nonconductive balls 400b may repeat random motion depending on the pressure of the flowing gas.

In addition, the nonconductive balls 400b may repeat random motion, by including the elastic material, even if the nonconductive balls 400b collide with each other inside the lift pin hole 710a or collide with the inner wall of the lift pin hole 710a. In this way, when the gas flows into the lift pin hole 710a, the nonconductive balls 400b may move randomly depending on the pressure of the gas, disturb the flow of the gas, and slow down the moving speed of the gas. Accordingly, it is possible to prevent an arcing phenomenon from occurring inside the lift pin hole 710a. In addition, the plasma processing equipment 1000e according to some embodiments may further include a structure which is connected to the lift pin hole 710a and discharges the gas flowing into the lift pin hole 710a from the gas filling unit 200 to the outside.

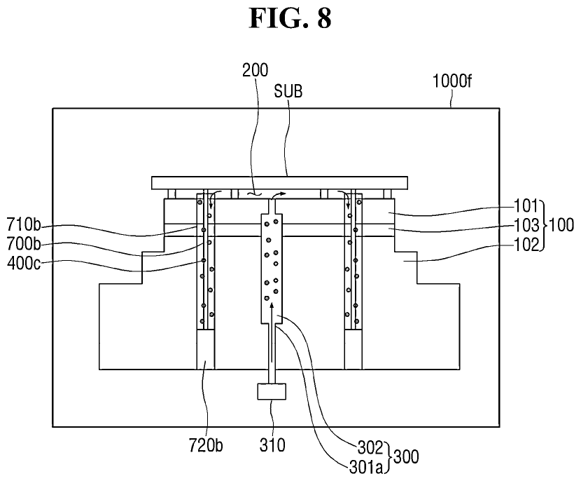

Referring to FIG. 8, next, a plasma processing equipment 1000f according to some embodiments may include a lift pin 700b and a lift pin hole 710b. The lift pin 700b may be placed or provided under the substrate SUB and may be formed or provided to penetrate the electrostatic chuck 100. The lift pin 700b may be placed or provided in the lift pin hole 710b and may move up and down through the lift pin holder 720b to adjust the height of the substrate SUB. In one embodiment, two lift pins 700b are shown in FIG. 8. In some embodiments, three or more lift pins 700b may be formed or provided under the substrate SUB to penetrate the electrostatic chuck 100 to adjust the height of the substrate SUB.

The lift pin hole 710b may be formed or provided to penetrate the electrostatic chuck 100, and may include a plurality of nonconductive balls 400c therein. The nonconductive balls 400c may include, but are not limited to, nonconductor materials such as ceramics. In some embodiments, the gas may flow from the gas filling unit 200 into the lift pin hole 710b. When the gas flows into the lift pin hole 710b, the nonconductive balls 400c may repeat random motion depending on the pressure of the flowing gas. In addition, the nonconductive balls 400c may repeat random motion, by including the elastic material, even if the nonconductive balls 400c collide with each other inside the lift pin hole 710b or collide with the inner wall of the lift pin hole 710b. In this way, when the gas flows into the lift pin hole 710b, the nonconductive balls 400c may move randomly depending on the pressure of the gas, disturb the flow of the gas, and slow down the moving speed of the gas. Accordingly, it is possible to prevent an arcing phenomenon from occurring inside the lift pin hole 710b.

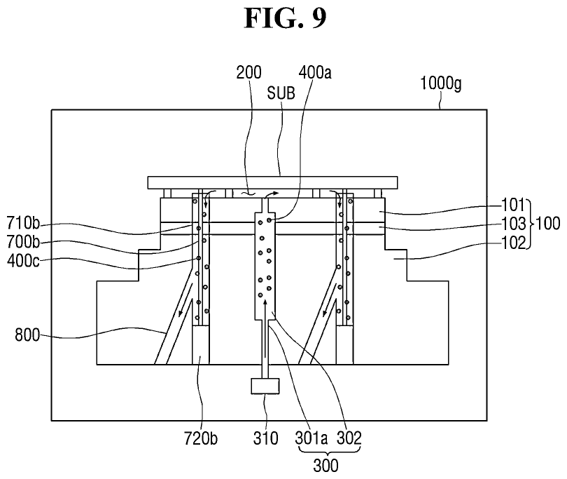

Referring to FIG. 9, next, a plasma processing equipment 1000g according to some embodiments may include a dump hole 800. The dump hole 800 may be connected to the lift pin hole 710b and discharge the gas injected into the lift pin hole 710b to the outside. If the gas only flows into the lift pin hole 710b and is not discharged to the outside, an arcing phenomenon may occur inside the lift pin hole 710b. Therefore, the plasma processing equipment 1000g according to some embodiments may have a structure in which gas injected into the lift pin hole 710b circulates by including the dump hole 800 connected to the lift pin hole 710b, and may prevent an arcing phenomenon.

FIG. 10 is an example diagram for describing a plasma processing equipment according to some embodiments.

Referring to FIG. 10, a plasma processing equipment 2000a according to some embodiments may be an ICP etching device, and may include a chamber 900, a coil 901, an electrostatic chuck 100, a gas filling unit 200, a gas supply unit 300, a gas exhaust unit 500, a focus ring 600, lift pins 700a and 700b, and lift pin holes 710a and 710b.

The chamber 900 may provide a manufacturing space of the semiconductor element (for example, a space in which a process such as plasma etching is performed through the plasma processing equipment 2000a). That is, the chamber 900 may have a closed space of a certain size inside. The chamber 900 may be formed or provided in various forms depending on the size of the substrate SUB or the like. For example, the chamber 900 may have a cylindrical shape corresponding to the disk-shaped substrate SUB, but the shape of the chamber 900 is not limited thereto. The chamber 900 may include a conductive member, such as aluminum, according to embodiments.

Spirally surrounded coils 901 along the outer surface may be provided on the outside of the upper part of the chamber 900. The coils 901 may be connected to a high-frequency power supply unit 903 that applies a source power through a matcher. The coils 901 may induce an electric field for generating a plasma inside the chamber 900. A gas supply pipe 905 for providing the process gas to the substrate SUB inside the chamber 900 may be provided above the chamber 900. The process gas includes, but is not limited to, an etching gas. For example, although the process gas may include at least one of CF₄, C₄F₆, C₄F₈, COS, CHF₃, HBr, SiCl₄, O₂, N₂, H₂, NF₃, SF₆, He or Ar, the kind of the process gas is not limited thereto. The gas supply pipe 905 is connected to a gas shower head 908 in which a plurality of gas diffusion holes 907 are formed or provided through a buffer chamber 906, and may spray a predetermined process gas toward the substrate SUB placed or provided on the electrostatic chuck 100. The gas supply pipe 905 may be connected to an external gas supply unit 904, and the gas supply unit 904 may supply the process gas to the chamber 900.

An outlet 909 may be formed or provided at the bottom of the chamber 900, and the outlet 909 may be connected to a vacuum pump 910, such as a dry pump. Products such as polymers generated during the etching process may be discharged to the outside through the outlet 909.

The high-frequency power supply unit 902 applies high-frequency power to the electrostatic chuck 100 to form an electric field, and activates the process gas supplied to the closed space of the chamber 900 by the electric field to a plasma state. In some embodiments, the power supply provided to the electrostatic chuck 100 through the high-frequency power supply unit 902 may be an RF power supply, but is not limited thereto. Plasma may be generated on the substrate SUB through the power supply provided to the electrostatic chuck 100 through the high-frequency power supply unit 902. As such, a substrate SUB processing process using plasma, such as substrate SUB surface etching may be performed, using the plasma generated in the chamber 900.

In some embodiments, the frequency of power supply provided to the electrostatic chuck 100 through the RF power supply unit 902 may be a mixture of high frequency and low frequency. For example, the frequency of the power supply provided to the electrostatic chuck 100 through the high-frequency power supply unit 902 may be a mixture of about 14 MHz and a low frequency such as 1 MHz and 2 MHz. As described above, when the frequency of the power supply provided to the electrostatic chuck 100 is lowered, the voltage applied to the chamber 900 increases, and arcing may occur in the portion penetrating into the chamber 900, for example, inside the gas supply unit 300 and the lift pin holes 710a and 710b. Therefore, in some embodiments of the present disclosure, a plurality of nonconductive balls 400a, a plurality of nonconductor ball 400b and a plurality of nonconductive balls 400c that randomly and repeatedly move depending on the pressure of the gas are placed or provided inside the gas supply unit 300, the lift pin hole 710a, and the lift pin hole 710b. Accordingly, it is possible to prevent the gas flowing into the gas supply unit 300, the lift pin hole 710a, and the lift pin hole 710b from receiving acceleration energy, thereby preventing an arcing phenomenon from occurring. Therefore, the withstand voltage performance of the plasma processing equipment 2000a can be improved. Also, the plasma processing equipment 2000a may have a structure in which the gas flowing into the gas filling unit 200 and the lift pin hole 710b circulates, by including the gas exhaust unit 500 and the dump hole 800. Accordingly, the amount of gas filled in the gas filling unit 200 may be quickly changed, the pressure of the gas provided to the lower side of the substrate SUB may be quickly changed in the process operation, and the temperature distribution of the substrate SUB may be quickly controlled. In addition, it is possible to prevent the gas from staying for a long time inside the gas supply unit 300 and the lift pin hole 710b, thereby preventing an arcing phenomenon from occurring.

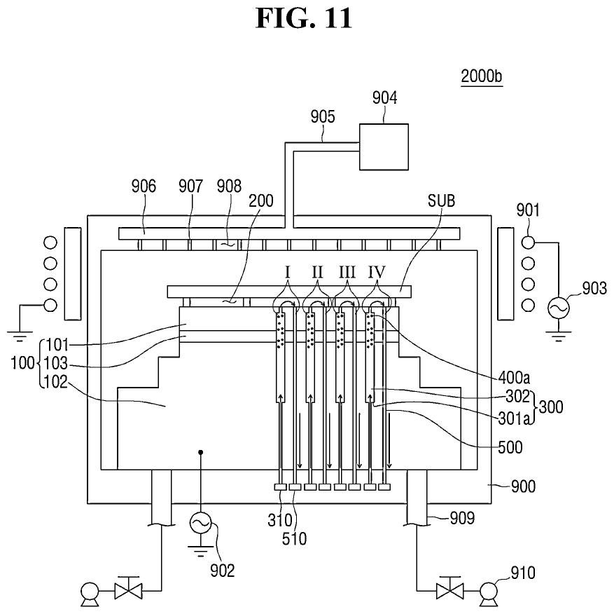

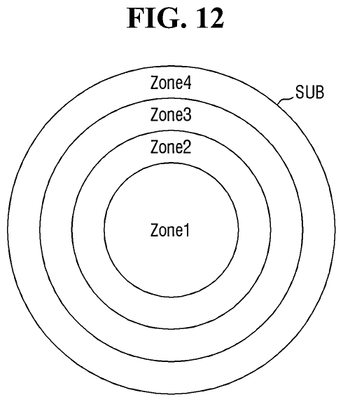

FIG. 11 is an example diagram for explaining the effects of the plasma processing equipment according to some embodiments. FIG. 12 is an example top view of a part of the plasma processing equipment of FIG. 11 viewed from above. Hereinafter, the effect of the plasma processing equipment including the gas supply unit and the gas filling unit will be described below referring to FIGS. 11 and 12.

First, referring to FIG. 11, a plasma processing equipment 2000b according to some embodiments may include two or more gas supply units 300 that penetrate the electrostatic chuck 100 to supply the gas to the gas filling unit 200, and two or more gas exhaust units 500 that discharge gas filled in the gas filling unit 200. Hereinafter, in FIGS. 11 and 12, a case in which four gas supply units 300 and four gas exhaust units 500 are placed or provided will be described as an example.

One gas supply unit 300 and one gas exhaust unit 500 may form a pair. For example, referring to FIG. 11, I, II, III, and IV may each correspond to the pair of gas supply units 300 and gas exhaust units 500 from a center zone to an edge zone of the electrostatic chuck 100 in order. Also, a pair of gas supply unit 300 gas exhaust unit 500 may correspond to one zone on the upper side of the substrate SUB.

For example, referring to FIGS. 11 and 12 together, the substrate SUB may have a disc shape, and the electrostatic chuck 100 and the chamber 900 may have a cylindrical shape correspond thereto. At this time, I, which is a pair of the gas supply unit 300 and the gas exhaust unit 500, may correspond to a first zone (Zone 1) on the upper side of the substrate SUB. Further, II, which is another pair of the gas supply unit 300 and the gas exhaust unit 500, may correspond to a second zone (Zone 2) on the upper side of the substrate SUB. Further, III and IV, which are still another pairs of the gas supply unit 300 and the gas exhaust unit 500, may correspond to a third zone (Zone 3) and a fourth zone (Zone 4) on the upper side of the substrate SUB, respectively.

At this time, since the pairs (I, II, III, and IV) of the gas supply unit 300 and the gas exhaust unit 500 are connected to different gas pressure controllers 310 and exhaust pumps 510, the gas pressure between zones inside the gas filling unit 200 corresponding to the pairs (I, II, III, and IV) of each gas supply unit 300 and gas exhaust unit 500 may be controlled individually. Therefore, the temperature of the zones (Zone 1, Zone 2, Zone 3, and Zone 4) on the upper side of the substrate SUB corresponding to the pairs (I, II, III, and IV) of each gas supply unit 300 and gas exhaust unit 500 may also be controlled individually.

In some embodiments, by making the number of nonconductive balls 400a included in each gas supply unit 300 different, the gas pressure between the zones inside the gas filling unit 200 corresponding to pairs (I, II, III, and IV) of each gas supply unit 300 and gas exhaust unit 500 may be individually controlled. For example, if the number of nonconductive balls 400a included in the gas supply unit 300 is large, the amount of gas filled in the gas filling unit 200 decreases, and the gas pressure provided to the lower side of the substrate SUB corresponding to the zone of the gas filling unit 200 may decrease. Further, if the number of nonconductive balls 400a included in the gas supply unit 300 is small, the amount of gas filled in the gas filling unit 200 increases, and the gas pressure provided to the lower side of the substrate SUB corresponding to the zone of the gas filling unit 200 may increase. This makes it possible to individually control the temperatures of zones (Zone 1, Zone 2, Zone 3, and Zone 4) on the upper side of the substrate SUB and reduce the temperature deviation between the zones (Zone 1, Zone 2, Zone 3, and Zone 4) on the upper side of the substrate SUB.

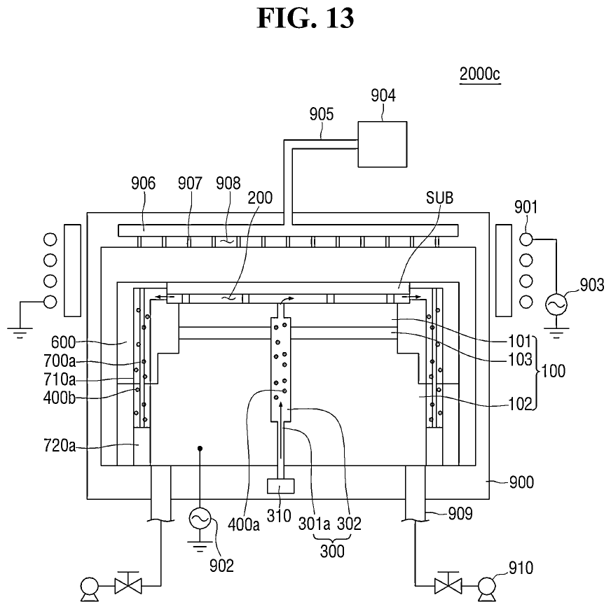

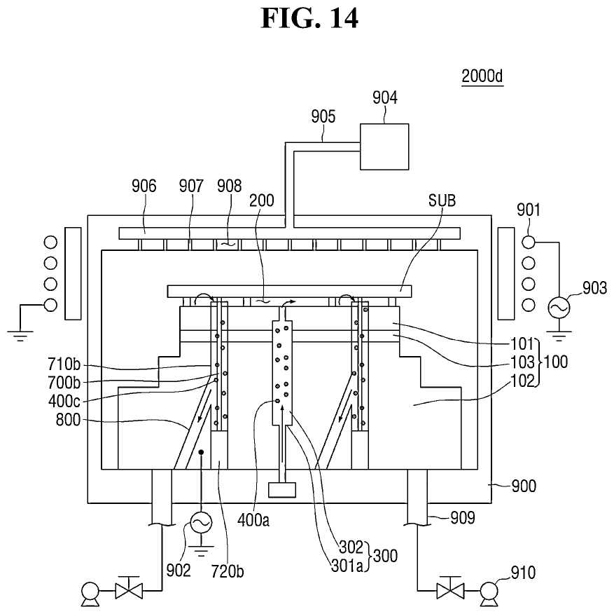

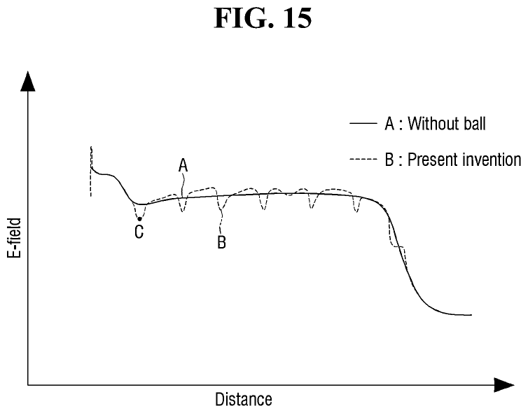

FIGS. 13 and 14 are example diagrams for explaining the effects of the plasma processing equipment according to some embodiments. FIG. 15 is an example graph for explaining the effect of the plasma processing equipment according to some embodiments. Effects of the plasma processing equipment 2000c and 2000d will be described below with reference to FIGS. 13 to 15.

First, referring to FIG. 13, the gas filled in the gas filling unit 200 through the gas supply unit 300 in the plasma processing equipment 2000c may flow out into the lift pin hole 710a. As such, as the gas that has flowed into the lift pin hole 710a flows below the lift pin hole 710a, an arcing phenomenon may occur on the inner wall of the lift pin hole 710a. Similarly, referring to FIG. 14, the gas filled in the gas filling unit 200 through the gas supply unit 300 in the plasma processing equipment 2000d may flow out into the lift pin hole 710b. When the gas that has flowed into the lift pin hole 710b flows below the lift pin hole 710b, an arcing phenomenon may occur on the inner wall of the lift pin hole 710b.

In order to prevent an arcing phenomenon from occurring inside (e.g., the inner walls of) the lift pin holes 710a and 710b, in some embodiments, a plurality of nonconductive balls 400b and 400c may each be placed or provided inside the lift pin holes 710a and 710b to prevent the gas flowing into the lift pin hole 710a and the lift pin hole 710b from obtaining acceleration energy, thereby preventing an arcing phenomenon from occurring.

Next, referring to FIG. 15, a graph A is a graph showing the magnitude of an electric field (E-field) with respect to a distance from each entrance of lift pin holes 710a and 710b into which gas flows to the inner points of each lift pin hole 710a and 710ba when the nonconductive balls 400b and 400c are not placed or provided inside the lift pin hole (710a shown in FIG. 13) and the lift pin hole (710b shown in FIG. 14). A graph B is a graph showing the magnitude of an electric field (E-field) with respect to a distance from each entrance of lift pin holes 710a and 710b into which gas flows to the inner points of each lift pin hole 710a and 710ba when the nonconductive balls 400b and 400c are placed or provided inside the lift pin hole (710a shown in FIG. 13) and the lift pin hole (710b shown in FIG. 14). Referring to the graph B, unlike the graph A, it may be seen that the magnitude of the electric field is measured to be small at a plurality of specific points (for example, a point C). In this way, when the plurality of nonconductive balls 400b and 400c are included inside the lift pin holes 710a and 710b, the magnitude of the electric field measured between the plurality of nonconductive balls 400b and 400c and the inner walls of the lift pin holes 710a and 710b may decrease. Accordingly, it is possible to prevent an arcing phenomenon that may occur inside the lift pin holes 710a and 710b when performing the substrate SUB processing process using plasma, thereby enhancing withstand voltage performance of the plasma processing equipment 2000c and 2000d.

While the present disclosure has been particularly illustrated and described with reference to example embodiments thereof, it will be understood by those of ordinary skill in the art that various changes in form and detail may be made therein without departing from the spirit and scope of the present disclosure as defined by the following claims. The example embodiments should be considered in a descriptive sense only and not for purposes of limitation.

What is claimed is:

1. A plasma processing equipment comprising:
an electrostatic chuck on which a substrate is provided;
a gas filling unit provided between the substrate and the electrostatic chuck;
a gas supply unit extending through the electrostatic chuck and connected to the gas filling unit, the gas supply unit comprising a plurality of first nonconductive balls; and
a focus ring provided along an edge of the electrostatic chuck.

2. The plasma processing equipment of claim 1, wherein the gas supply unit further comprises:
at least one gas inlet into which a gas flows; and
a gas supply pipe connected to the at least one gas inlet and configured to supply the gas from the at least one gas inlet to the gas filling unit.

3. The plasma processing equipment of claim 2, wherein the at least one gas inlet is provided on a side part of the gas supply pipe.

4. The plasma processing equipment of claim 3, wherein the at least one gas inlet comprises at least two gas inlets provided on the side part of the gas supply pipe.

5. The plasma processing equipment of claim 4, wherein the at least two gas inlets are spaced apart at equal intervals.

6. The plasma processing equipment of claim 1, further comprising a gas exhaust unit extending through the electrostatic chuck and connected to the gas filling unit.

7. The plasma processing equipment of claim 1, further comprising a first lift pin penetrating the focus ring and the edge of the electrostatic chuck, and configured to adjust a height of the focus ring.

8. The plasma processing equipment of claim 7, wherein the first lift pin is provided inside a first lift pin hole penetrating the focus ring and the edge of the electrostatic chuck, and
wherein the first lift pin hole comprises a plurality of second nonconductive balls.

9. The plasma processing equipment of claim 1, further comprising a second lift pin provided below the substrate and penetrating the electrostatic chuck, the second lift pin being configured to adjust a height of the substrate.

10. The plasma processing equipment of claim 9, wherein the second lift pin is provided in a second lift pin hole penetrating the electrostatic chuck, and
wherein the second lift pin hole comprises a plurality of third nonconductive balls.

11. A plasma processing equipment comprising:
an electrostatic chuck on which a substrate is provided;
a gas filling unit provided above the electrostatic chuck and configured to provide a gas pressure to a lower side of the substrate;
a gas supply unit connected to the gas filling unit and configured to supply a gas to the gas filling unit, the gas supply unit comprising a plurality of first nonconductive balls; and
a gas exhaust unit connected to the gas filling unit and configured to discharge the gas supplied from the gas supply unit to the gas filling unit.

12. The plasma processing equipment of claim 11, wherein the gas supply unit further comprises:
at least one gas inlet into which the gas flows; and
a gas supply pipe connected to the at least one gas inlet and configured to supply the gas to the gas filling unit.

13. The plasma processing equipment of claim 12, wherein the plurality of first nonconductive balls is configured to move inside the gas supply pipe based on a pressure of the gas.

14. The plasma processing equipment of claim 12, wherein a total volume of the plurality of first nonconductive balls is less than or equal to 20% of a volume of the gas supply pipe per a number of the at least one gas inlet connected to the gas supply pipe.

15. The plasma processing equipment of claim 11, further comprising a first lift pin provided below the substrate and penetrating the electrostatic chuck, the first lift pin being configured to adjust a height of the substrate.

16. The plasma processing equipment of claim 15, wherein the first lift pin is provided inside a first lift pin hole penetrating the electrostatic chuck, and
wherein the first lift pin hole comprises a plurality of second nonconductive balls.

17. The plasma processing equipment of claim 16, further comprising a dump hole connected to the first lift pin hole and configured to discharge a gas injected into the first lift pin hole.

18. A plasma processing equipment comprising:
a chamber:
a coil configured to induce an electric field for generating a plasma inside the chamber:
an electrostatic chuck inside the chamber and on which a substrate is provided:
a gas filling unit configured to provide a gas pressure to a lower side of the substrate:
a gas supply unit connected to the gas filling unit and configured to supply a gas to the gas filling unit, the gas supply unit comprising a plurality of first nonconductive balls:
a gas exhaust unit connected to the gas filling unit, and configured to discharge the gas to the gas filling unit:
a focus ring provided in an annular shape along an edge of the electrostatic chuck:
a first lift pin hole comprising a first lift pin and a plurality of second nonconductive balls, wherein the first lift pin penetrates the focus ring and the edge of the electrostatic chuck and is configured to adjust a height of the focus ring; and
a second lift pin hole comprising a second lift pin and a plurality of third nonconductive balls, wherein the second lift pin is provided below the substrate, and configured to penetrate the electrostatic chuck to adjust the height of the substrate.

19. The plasma processing equipment of claim 18, wherein the plurality of first nonconductive balls is configured to move inside the gas supply unit based on a pressure of the gas.

20. The plasma processing equipment of claim 18, wherein the gas supply unit comprises:
a gas inlet into which the gas flows; and
a gas supply pipe connected to the gas inlet and configured to supply the gas to the gas filling unit, and
wherein the gas inlet is provided on a side part of the gas supply pipe.
